(19) United States
(12) Patent Application Publication
(10) Pub. No.: US 2010/0260409 A1
(43) Pub. Date: Oct. 14, 2010

(54) IMAGING MEASUREMENT SYSTEM WITH PERIODIC PATTERN ILLUMINATION AND TDI

(75) Inventor: Meir Ben-Levy, Haifa (IL)

Correspondence Address: DR. MARK M. FRIEDMAN;C/O BILL POLKINGHORN - DISCOVERY DISPATCH, 9003 FLORIN WAY, UPPER MARLBORO, MD, 20772, US

(73) Assignee: MACHVISION, Inc., Hsinchu Science Park (TW)

(21) Appl. No.: 12/678,155

(22) PCT Filed: Apr. 6, 2008
(86) PCT No.: PCT/IL08/00475

§ 371 Date: Mar. 15, 2010

Related U.S. Application Data
(60) Provisional application No. 60/972,802, filed on Sep. 16, 2007.

(51) Int. Cl. G06K 9/00; H01L 27/146; H04N 5/335

(52) U.S. Cl. 382/141; 250/208.1; 348/295; 348/E05.091

(57) ABSTRACT

A patterned TDI sensor comprising an array of pixels having respective sensitivities to light that varies according to a periodic pattern across said array of pixels, for high throughput applications of imaging and measurement with patterned illumination such as structured illumination, Moire techniques, 3D imaging and 3D metrology. An object is measured by scanning the object with illumination that varies periodically across the object, imaging the object with a patterned TDI sensor having a repetition length matched with the repetition length of the illumination and analyzing the output signal of the TDI sensor to extract information such as height or image of the object.

### FIELD AND BACKGROUND OF THE INVENTION

The invention relates to imaging measurement systems with periodic pattern illumination, also known as structured illumination or Moire techniques and more specifically to improving the throughput of such systems.

Imaging and measurement systems with periodic pattern commonly use sinusoidal periodic illumination to improve the imaging resolution, to distinguish image information at the focal plane and to measure the heights of objects. These techniques have the potential of being more light efficient, faster and of providing better resolution than standard confocal imaging microscopy or standard triangulation height measurement systems. See for example, Rainer Heintzmann, Handbook of Biologic Confocal Microscopy 3^{rd} edition, chapter 13 “Structured Illumination Methods”, Springer 2006. The main limitations to throughput come from insufficient light intensity, the need to image the same object several times while changing the phase of the illumination and the multiple calculations required to extract the information from the optical images.

Whether used to extract an image or to measure height, most of the systems using periodic pattern illumination include the elements of:
Illuminating an object with a periodic pattern.
Scanning the object while varying the phase of the pattern relative to the object.
Imaging the object while scanning.
Mathematical analysis to extract the required parameters (height or image).

U.S. Pat. No. 05,867,604 discloses a method to improve lateral resolution of optical imaging system by scanning the object with periodic pattern illumination. According to the teaching of U.S. Pat. No. 05,867,604, if an object is illuminated with periodic pattern illumination, two synthetic images can be extracted by numerical processing the optical image namely S₁ and S₂. S₁ is a linear transformation of the reflectivity of the object with a better transfer function than the optical Modulation Transfer Function (MTF), in the high frequencies range. Therefore S₁ has a better resolution to identify details of the object than the optical image by itself. S₂ is the Hilbert transform of S₁. S₁ and S₂ can distinguish information in focus only (slicing quality), because out of focus, the modulation of the periodic pattern illumination fades.

Beyond slicing and resolution improvement of imaging, industrial metrology machines use periodic pattern illumination technique for height measurement of object like semiconductors bumps. If the object is illuminated with periodic pattern illumination from one direction at angle α and imaged from a different direction at angle β, the phase of the pattern at the image plane will depend on the height of the object. This configuration for height measurement is also called Moire technology, because of the use of gratings and illumination with tilted angles. U.S. Pat. No. 07,023,559 discloses a measurement system with periodic pattern illumination to measure height of objects such as solder bumps. According to the teaching of U.S. Pat. No. 07,023,559, a grid of light is projected on an object creating a periodic pattern illumination and a camera images the object from different angle. The height of the object is analyzed from several images taken by the camera, wherein each image has a different position of the grid (different phase). The height of the object is related to the phase measured in this process through calibration with a known target.

U.S. Pat. No. 06,603,103 discloses a measurement system with periodic pattern illumination and using continuous scanning. According to the teaching of U.S. Pat. No. 06,603,103, the object is illuminated by a grid of light and imaged by three lines of CCD (trilinear array). The object is moved with constant velocity, so any point of the object is imaged three times, each time by a different CCD line and each time in different phase. Fourier analysis of the three images can analyze the phase of the signal and thus measure the height of the object.

It is common to use a Time Delayed Integration (TDI) sensor in continuous scanning with uniform illumination, but not with periodic patterned illumination. U.S. Pat. No. 04,877,326 discloses an inspection system including an illumination apparatus designed to provide substantially uniform focused illumination along a narrow line and a TDI sensor for imaging the object. According to the teachings of U.S. Pat. No. 04,877,326, the application of TDI to inspection is attractive because inspection processes tend to be light limited and TDI allows the integration time to be increased without slowing down inspection.

Most scanning systems with a TDI sensor such as described by U.S. Pat. No. 04,877,326 cannot use periodic pattern illumination because the process of Time Delay Integration will eventually eliminate any information of the original pattern of the illumination.

U.S. Pat. No. 06,714,283 discloses a sensor and method for range measurements using a TDI device with structured illumination. To avoid losing the range information in the TDI process, the exposure of the device to the reflection of the light beam is restricted to the first integration period of the acquisition cycle of the TDI device. By restricting the TDI to only one integration period according to the teaching of U.S. Pat. No. 06,714,283 the loss of phase information is avoided, but it also prevents using the TDI in light limiting applications because only a fraction of the potential integration time of the sensor is used.

### SUMMARY OF THE INVENTION

The present invention overcomes the limitations of the prior art by providing an optical scanning imaging system that illuminate the object with a periodic pattern light and images the object with a patterned sensitivity Time Delayed Integration (TDI) sensor. The patterned sensitivity TDI sensor includes an array of pixels whose light sensitivity varies periodically across the array, having the same period as the illumination when imaged to the sensor. For example, the sensor can be masked, so that some of the pixels are completely or partially blocked from light. The integration process of the TDI sensor with patterned sensitivity becomes part of the mathematical analysis required in structured illumination to extract phase and amplitude, therefore it saves calculation time and enhances throughput.

The invention discloses a patterned TDI sensor for imaging an object, including an array of pixels, having respective sensitivities to light that vary according to a periodic pattern across the array. The invention further provides a method of inspecting the object including the steps of scanning the object with illumination that varies periodically across the object, imaging the object with a patterned sensitivity TDI sensor with a repetition length matched with a repetition length of the illumination and analyzing the output signal of the TDI sensor to extract information about the object. Such information may be an image or height of the object.

Hence, disclosed herein is a TDI sensor for imaging an object, including an array of pixels, the pixels having respective sensitivities to light that vary according to a periodic pattern across the array.

In many embodiments, the pixels are arranged in a plurality of columns and a phase shift of the periodic pattern is introduced between adjacent columns. In one such embodiment, the pattern has a period length of six pixels along each column and the phase of the pattern shifts by two pixels between adjacent columns. In another such embodiment, the pattern has a period length of four pixels along each column and the phase of the pattern shifts by one pixel between adjacent columns.

Also disclosed herein is a method of inspecting an object, including the steps of: (a) scanning the object with illumination that varies periodically across the object; (b) imaging the object with a patterned sensitivity TDI sensor that includes a plurality of pixels having a periodically varying light sensitivity, the light sensitivity having a repetition length matched with a repetition length of the illumination; and (c) analyzing an output signal of the TDI sensor to extract information about the object.

Normally, the information includes the height of the object and/or an image of the object. In some embodiments the image includes only in-focus information of the object. In other embodiments, the image includes information in phase with the periodic pattern illumination and/or information 90 degrees out of phase with the periodic pattern illumination.

Also disclosed herein is an imaging apparatus including the disclosed TDI sensor and an illuminator for illuminating an object with a periodic pattern illumination, wherein the periodic pattern illumination is matched with the periodic pattern of the TDI pixels.

### BRIEF DESCRIPTION OF THE DRAWINGS

The invention is herein described, by way of example only, with reference to the accompanying drawings, wherein:

FIG. 1 is a schematic view of a system for inspecting an object with periodic pattern illumination and a patterned sensitivity TDI sensor;

FIG. 2 shows a partial scheme of the pixels array of the sensitivity patterned TDI sensor in one embodiment of the invention;

FIG. 3 shows another scheme of the pixels array of the sensitivity patterned TDI sensor;

FIG. 4 shows an optical setup to image an object with slicing and improved resolution capabilities in one embodiment of the invention;

FIG. 5 demonstrates the slicing capabilities of the optical setup of FIG. 4 in one focal plane;

FIG. 6 demonstrates the slicing capabilities of the optical setup of FIG. 4 in a different focal plane;

FIG. 7 shows an optical setup to measure height of an object with non perpendicular illumination angle, in a different embodiment of the invention; and

FIG. 8 shows a detailed view of the TDI sensor of the invention.

### DESCRIPTION OF THE PREFERRED EMBODIMENTS

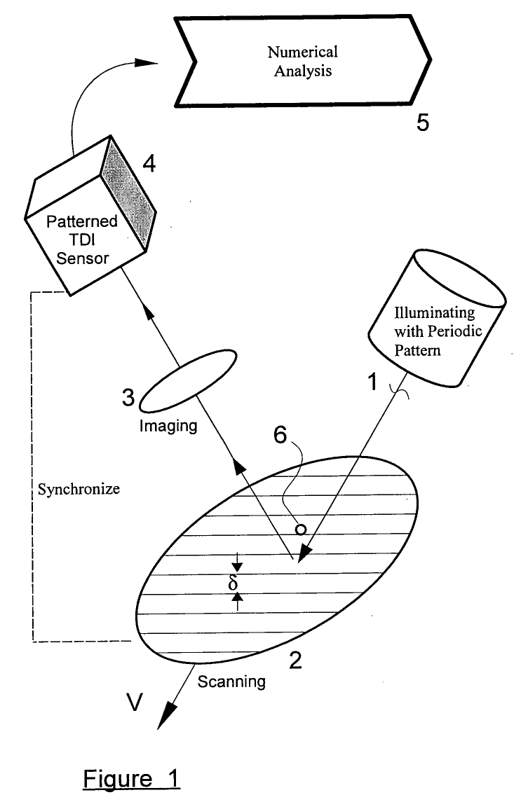

The invention can be better understood from FIG. 1, showing a schematic layout of an embodiment of the invention. FIG. 1 shows an Object 2, illuminated with a periodic illumination pattern 1. The means to illuminate with the periodic pattern may include projecting an image of a grating illuminated with a back light source. The intensity of the periodic pattern illumination preferably varies sinusoidally with repetition length δ. The optical imaging system 3 creates an optical image of the object on a patterned sensitivity TDI sensor 4. The TDI sensor converts the optical image to numerical data while scanning the object with a constant velocity V, synchronized with the TDI sensor in the common way of line camera synchronization and processor 5 analyses the data to extract information of the object.

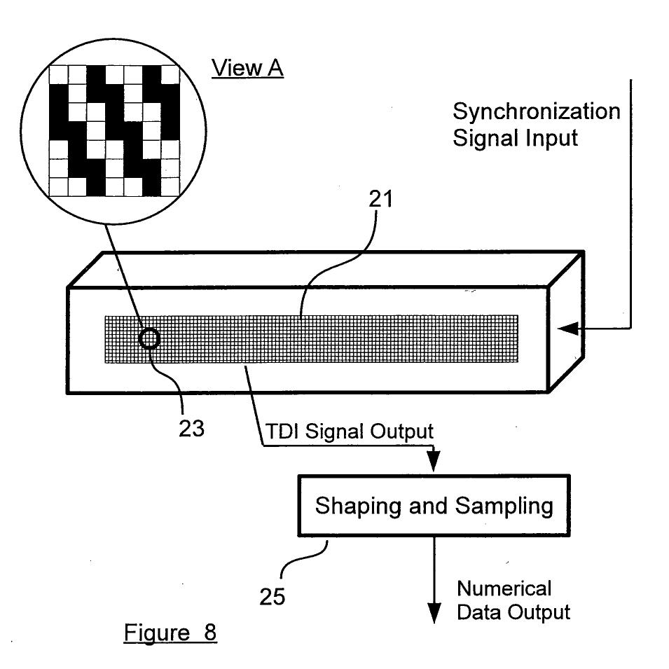

FIG. 8 show a more detailed view of the TDI sensor. The TDI sensor consist an array of pixels 21, sensitive to light intensity. Typical arrays can have 128 lines and 4,000 columns of pixels. In the process of Time Delay Integration of the TDI sensor, a pixel receives electrical charge from the adjacent pixel in the same column, adds more electric charge according to the light intensity and transfers the charge to the next pixel along the column. The charge transfer from one pixel to the next is synchronized with the scanning velocity of the object. The TDI signal output is the integration of charges created along the column while imaging the same point of the object. After sampling the numerical data is sent to processor 5 of FIG. 1. View A of FIG. 8 is a magnified view of a small area 23 of the pixels array.

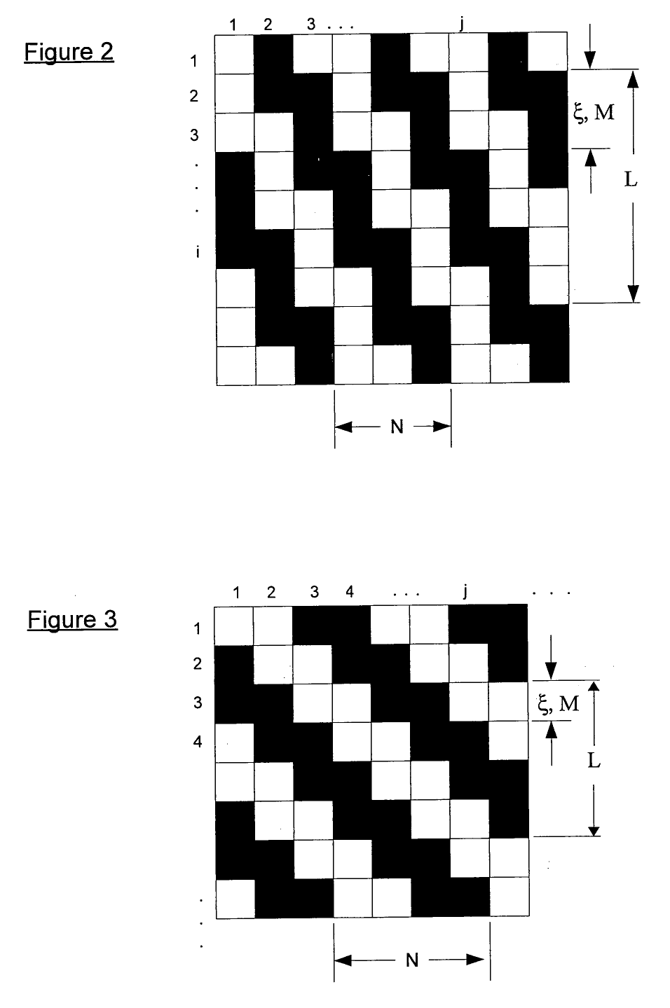

FIG. 2 shows a partial scheme of the pixels array of the sensitivity patterned TDI sensor in one embodiment of the invention, showing View A of FIG. 8 in more details. The TDI array of the preferred embodiment includes active pixels and inactive pixels marked in white and black squares respectively. Active pixels are sensitive to light intensity and inactive pixels are rendered insensitive to light, for example by masking those pixels. In the process of Time Delay Integration, an active pixel receives electrical charge from the adjacent pixel in the same column, adds more electric charge according to the light intensity and transfers the charge to the next pixel along the column. The charge transfer from one pixel to the next is synchronized with the scanning velocity of the object. An inactive pixel receives and transfers charges, but an inactive pixel is not sensitive to light and so an inactive pixel does not add charges. An inactive pixel may be masked to prevent light accessing the pixel, or an inactive pixel may be electrically inactive. The active and inactive pixels form a repetitive pattern with repetition length of L pixels, matching with the illumination repetition length δ in a way that:

$$L = \frac{G δ}{p} \qquad ( 1 )$$

where G is the optical magnification and p is the pixel size. All columns of the TDI pixel array have the same periodic pattern but there is a shift between adjacent columns of M pixels, which creates a phase shift (in radians) between adjacent columns of:

ξ=2 π M/L (2)

The integer N defined by:

N=M/L (3)

N is the repetition length along the line of the pixels array, meaning that the pattern of active and inactive pixels is identical every N columns. L and M should be so chosen that N is an integer. An example having L=6, M=2 and N=3 pixels is shown in FIG. 2.

FIG. 3 shows another embodiment in which L=4, M=1 and N=4, other configurations may also be considered. Since the TDI sensor has a patterned sensitivity matched with the illumination pattern, the output at any column in the process of Time Delay Integration measures amplitude and phase information of the image, and the adjacent column of the sensor measures basically the same amplitude with phase shift equal to ξ as defined in equation (2). Fourier analysis by processor 5 of FIG. 1, over a set of N adjacent columns, analyzes both amplitude-and phase of the image. Processor 5 further analyzes the height of the object, which is related to the phase. In a different optical configuration, processor 5 also analyzes the synthetic images S₁ and S₂, which are related to both amplitude and phase.

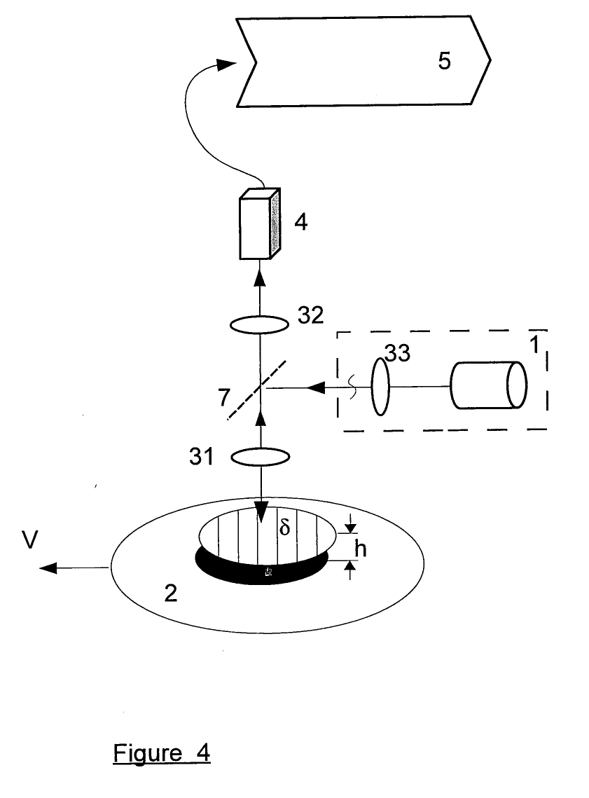

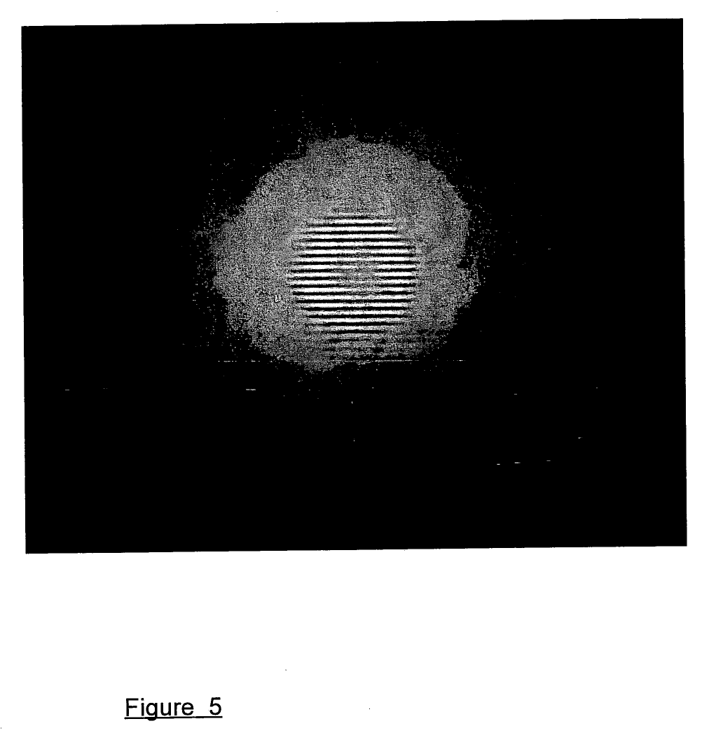

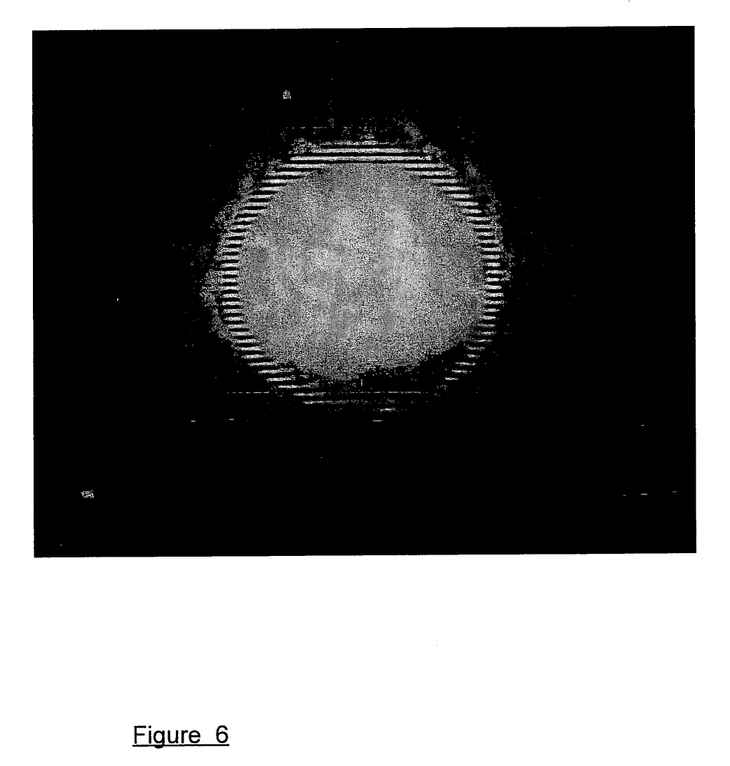

FIG. 4 shows an optical setup for imaging an object with slicing and improved resolution capabilities. The object is illuminated with a periodic pattern 1 and is imaged in the same angular direction perpendicular to the object 2 with a patterned sensitivity TDI sensor 4. A beam splitter 7 is used to combine the illumination and the imaging light beams. The same objective 31 is used to project the illumination pattern and to image the object. The optical setup of FIG. 4 consists of two tube lenses, tube lens 33 for the illumination and tube lens 32 for imaging to the TDI sensor. As in FIG. 1, processor 5 analyzes the amplitude and phase of the image acquired by TDI sensor 4. FIGS. 5 and 6 demonstrate the slicing capabilities of periodic pattern illumination in imaging a 100 μm-high ball-shaped solder bump. FIG. 5 shows the image of the solder bump at a higher focal plane than FIG. 6. Only a narrow slice within the depth of focus is modulated by the illumination pattern.

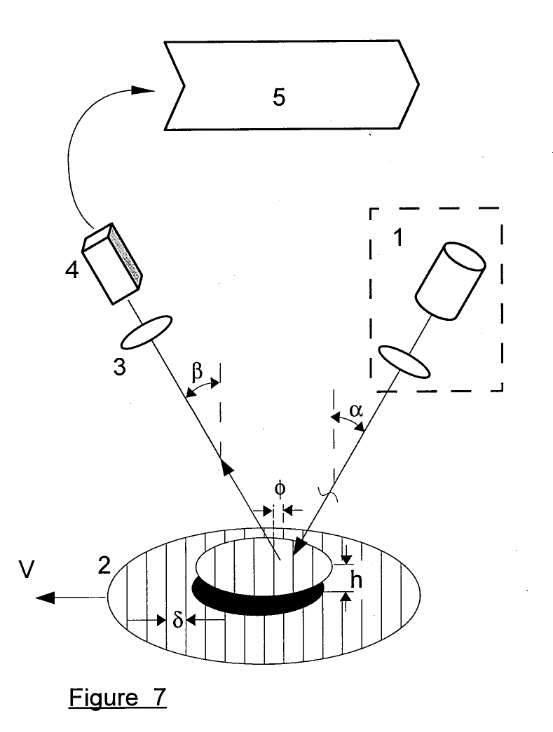

FIG. 7 shows an optical setup for measuring the height of an object with periodic pattern illumination. The object 2 is illuminated with periodic pattern 1 at angle α and it is imaged from angle β. The optical imaging system 3 creates an optical image of the object on a patterned sensitivity TDI sensor 4. TDI sensor 4 converts the optical image to an electrical signal, which is converted to numerical data while scanning the object with a constant velocity V. Processor 5 analyses the data to extract height information of the object. Depending on the illumination and imaging angles, there is a linear relationship between the height of the object h and the phase shift φ imaged at the image plane. Because the angles α and β are affected by mechanical tolerances, the dependency of phase and height should be measured and calibrated. The calibration can be done using a calibration target with a plurality of features having different known heights (e.g. a step target) or by moving a flat target to change the height of the target with known displacement. It is also possible to use a spherical shape target calibrated by an interferometer.

Mathematical Formulations

To better understand the imaging system of FIG. 1, consider a point 6 on the object moving with velocity V relative to illumination 1 and optics (either object 2 is moved relative to illumination 1 or illumination 1 is moved relative to object 2). While moving, point 6 is imaged to a sequence of pixels along the same column j of the TDI sensor. For a sine function illumination having a period length δ matching at the image plane to L pixels according to equation (1), the optical image intensity of point 6, I(i,j) measured at the TDI sensor 4 of image 1, satisfies:

I(i,j)=B₀+B₁ cos(2 π i/L+θ_{I}) i=1, 2, 3 . . . i(t) . . . i_{Max} (4)

where B₀ and B₁ are constants that are independent of time, θ_{I} is the phase at the image plane and i=1, 2, 3 . . . is the line index of the pixel to which point 6 is imaged. The index i varies in time while point 6 is moving with velocity V. Any pixel (i,j) creates charge according to the intensity of the image and the electrical sensitivity of the pixel to light. As the active and inactive pixels of the TDI create a periodic pattern with period L, the sensitivity q(i,j) of the TDI pixels, in term of charge created in response to image intensity, can be written in form of series of harmonics:

q(i,j)=C₀+C₁ cos(2 π i/L+θⱼ)+C₂ cos(4 π i/L+2θⱼ)+ . . . (5)

Where C₀, C₁, . . . are constants, and θⱼ is the phase of the TDI pattern along column j. To evaluate the total charge output by the TDI sensor, resulting from imaging of point 6, we have to multiply the intensity of equation (4) with the sensitivity of equation (5) and sum up for i=1, 2, 3 . . . to iₘₐₓ. The resulting charge at column j is Q(j) satisfying:

Q(j)=Σ {C0+C1 cos(2 π i/L+θⱼ)+C2 cos(4 π i/L+2θ)+ . . . }*{B0+B1 cos(2 π i/L+θ)} (6)

After summation, the resulting Q(j) can be written in the form of:

Q(j)=D₀+D₁ cos(ψ) (7)

ψ=θ_{I}−θⱼ

In equation (7), D₀ is the charge resulting from B₀, the uniform component of the optical image of point 6 in equation (4). D₀ is related to the object as an image, through the Modulation Transfer Function (MTF) of optical system 3 of FIG. 1. D₁ is the charge resulting from B₁, the sinusoidal component of the image of point 6 in equation (4). D₁ is related to the object as an image with Modulation Transfer Functions like D₀ and it has the slicing quality, meaning that only information within the limited depth of focus can contribute to the image. Phase w is the phase of the optical image measured relative to the phase of the pattern of the sensor. After sampling, the charges are converted to numbers. One role of processor 5 is the numerical analysis required to estimate D₀, D₁ and ψ. We assume that the optical image of equation (7) is approximately constant within N adjacent columns. This assumption is valid if the object is flat within N pixels or if the optical point spread is as large as N pixels. With this assumption, the TDI output of N adjacent columns is:

$$Q ( j ) = \sim {D}_{0} + {D}_{1} cos ( ψ ) \\ Q ( j + 1 ) = \sim {D}_{0} + {D}_{1} cos ( ψ + ξ ) \\ ⋮ \\ Q ( {j}_{+ N - 1} ) = \sim {D}_{0} + {D}_{1} cos ( ψ + ( N - 1 ) ξ ) \qquad ( 8 )$$

where N, ξ are defined in equations (2) and (3) and where:

N ξ=2 π (9)

From (8) and (9), a Fourier analysis of N data points Q(j), Q(j+1), . . . Q(j+N−1) extracts estimation of D₀, D₁ and ψ.

For example, consider the patterned pixels array of FIG. 2, where N=3 and ξ=2π/3. The set of N adjacent columns Q(j−1), Q(j) and Q(j+1) base the estimation of D₁ by:

{D₁}²=˜{Q(j−1)sin(−2π/3)+Q(j+1)sin(2π/3)}²+{Q(j−1)cos(−2π/3)+Q(j)+Q(j+1)cos(2π/3)}² (10)

and the same set Q(j−1), Q(j) and Q(j+1) for estimation of ψ:

$$tan ( ψ ) ≅ \frac{\{ Q ( j - 1 ) sin ( - 2 π / 3 ) + Q ( j + 1 ) sin ( 2 π / 3 ) \}}{Q ( j - 1 ) cos ( - 2 π / 3 ) + Q ( j ) + Q ( j + 1 ) cos ( 2 π / 3 )} \qquad ( 11 )$$

The synthetic image in phase with the illumination S₁ and the synthetic image 90 degrees out of phase with the illumination S₂ as defined by U.S. Pat. No. 05,867,604 are estimated:

S₁=D₁ cos(ψ−ψₘ) (12)

S₂=D₁ sin(ψ−ψₘ) (13)

where ψₘ is a reference phase, that can be calibrated by measuring over a mirror target because a mirror target does not introduce phase shifts and the phase of the image is the same phase of the illumination.

While the invention has been described with respect to a limited number of embodiments, it will be appreciated that many variations, modifications and other applications of the invention may be made. Therefore, the claimed invention as recited in the claims that follow is not limited to the embodiments described herein.

What is claimed is:

1. A TDI sensor for imaging an object, comprising an array of pixels, said pixels having respective sensitivities to light that vary according to a periodic pattern across said array.

2. The TDI sensor of claim 1 wherein said pixels are arranged in a plurality of columns and wherein a phase shift of said periodic pattern is introduced between adjacent said columns.

3. The TDI sensor of claim 2, wherein said pattern has a period length of six said pixels along each column.

4. The TDI sensor of claim 2, wherein said phase of said pattern shifts by two said pixels between adjacent said columns.

5. The TDI sensor of claim 2, wherein said pattern has a period length of four said pixels along each column.

6. The TDI sensor of claim 2, wherein said phase of said pattern shifts by one said pixel between adjacent said columns.

7. A method of inspecting an object comprising the steps of:
(a) scanning the object with illumination that varies periodically across the object;
(b) imaging the object with a patterned sensitivity TDI sensor that includes a plurality of pixels having a periodically varying light sensitivity, the light sensitivity having a repetition length matched with a repetition length of said illumination; and
(c) analyzing an output signal of the TDI sensor to extract information about the object.

8. The method of claim 6 wherein said information includes a height of the object.

9. The method of claim 6 wherein said information includes an image of the object.

10. The method of claim 8 wherein said image includes only in-focus information of the object.

11. The method of claim 8 wherein said image includes information in phase with said periodic pattern illumination.

12. The method of claim 8 wherein said image includes information 90 degrees out of phase with said periodic pattern illumination.

13. An imaging apparatus comprising the TDI sensor of claim 1 and an illuminator for illuminating an object with a periodic pattern illumination, wherein said periodic pattern illumination is matched with said periodic pattern of the TDI pixels.
